(19) United States
(12) Patent Application Publication
(10) Pub. No.: US 2026/0343808 A1
(43) Pub. Date: Oct. 29, 2026

(54) EXTERNALLY MOUNTABLE MANIFOLD MODULE FOR IMMERSION COOLING

(71) Applicant: HEWLETT PACKARD ENTERPRISE DEVELOPMENT LP, Spring, TX (US)

(72) Inventors: Austin Edward Rodriguez, The Woodlands, TX (US); Keith Allen Sauer, Spring, TX (US); Steven Dale Webster, Montgomery, TX (US)

(21) Appl. No.: 19/191,146

(22) Filed: Apr. 28, 2025

(51) Int. Cl. H05K 7/20

(52) U.S. Cl. CPC H05K 7/20272; H05K 7/20236; H05K 7/20772

(57) ABSTRACT

An information processing system includes a system board comprising electronic components, a chassis, and a manifold module. The chassis comprises a base to support the system board, a pair of side walls, a front panel, and a rear panel. The manifold module comprises a manifold having a manifold body defining an interior chamber, a fluid inlet fluidically coupled to the interior chamber, and a plurality of fluid outlets fluidically coupled to the interior chamber. A set of mounting arms is coupled to the manifold body. Each mounting arm comprises a latch configured to engage with a latch point coupled to one of the side walls to mount the manifold module to the chassis in a position outside the chassis adjacent the rear panel or the front panel.

Information processing systems, (e.g., servers) generate heat during operation and, if the heat is not dissipated or cooling is not provided, damage can occur to various components within the system. One way to provide cooling to a system is through the use of airflow through the system, such as by using fans disposed within the system, with airflow over components providing cooling. Another way to provide cooling to a system is through the use of liquid cooling, where coolant liquids flowing over components remove heat from the system.

### BRIEF DESCRIPTION OF THE DRAWINGS

The present disclosure can be understood from the following detailed description, either alone or together with the accompanying drawings. The drawings and related description of the figures are included to provide a further understanding of the present disclosure and are incorporated in and constitute a part of this specification. The drawings illustrate one or more nonlimiting aspects and implementations of the present teachings and together with the description explain certain principles and operation. In the drawings:

FIG. 1 is a block diagram of a system including a manifold module.

FIG. 2 is a perspective view of a manifold module.

FIG. 3A is a top view of the manifold module of FIG. 2.

FIG. 3B is a top view of the manifold module of FIG. 2 with nozzles and plugs installed.

FIG. 3C is a top view of the manifold module of FIG. 2 with multiple different types of nozzles installed.

FIG. 4 is a front view of the manifold module of FIG. 2.

FIG. 5 is a detail view of a mounting arm of the manifold module of FIG. 2.

FIG. 6 is another detail view of the mounting arm of the manifold module of FIG. 2.

FIG. 7 is a perspective view of an information processing system including the manifold module of FIG. 2.

FIG. 8 is a detail perspective view of the information processing system of FIG. 7 without the manifold module installed.

FIG. 9A is a detail side view of the information processing system of FIG. 7 with the manifold module installed and brackets in a closed state.

FIG. 9B is a detail side view of the information processing system of FIG. 7 with the manifold module installed and brackets in an open state.

FIG. 10 is a method for adapting a system to include a manifold module for immersion cooling.

### DETAILED DESCRIPTION

Information processing components, such as CPUs, are increasing in power and heat generation, which is making it increasingly difficult to efficiently cool the system via airflow. As heat generation increases, greater volumes of air must be moved through the system to achieve the same level of cooling. The increase in air volume through the system results in increased power consumption and increased noise. In addition, as the amount of air to be moved through the system increases, costs for the various components, such as fans and heat sinks, also increase.

One alternative method for cooling an information processing system is liquid cooling, in which liquid coolant is used to remove heat from a system. One form of liquid cooling is direct liquid cooling (DLC), in which liquid coolant flows through a system using tubes/pips, and heat is extracted from heat generating components of the system into the liquid coolant via cold plates coupled to the components. DLC is often used in information processing systems having high component density, such as supercomputers or high-performance compute systems, where there are multiple components generating high amounts of heat. DLC is highly efficient at removing heat from a system, however, DLC has a high cost due to the addition of further components, such as cold plates and coolant pipes, to the system. Due to the complexity of many DLC cooled systems, these additional components are often customized for each particular system, meaning that many components cannot be easily reused.

Immersion cooling, on the other hand, involves submerging part or all of an information processing system in a tank of an electrically non-conductive liquid coolant, such as a dielectric liquid. This allows the liquid coolant to contact some or all of the information processing components, such that heat generated by the components can be discharged into the coolant. The heated coolant can then be circulated through a heat exchanger to remove the heat before being recirculated into the tank. Immersion cooling represents an efficient method of cooling a system without a corresponding increase in power or noise output, as may occur in an air-cooled system. Similarly, immersion cooling allows some of the benefits of direct liquid cooling, namely, the increase in heat able to be removed from the system thanks to the use of a coolant fluid, without requiring a custom designed cooling system based on the particular information processing system. As such, the increase in accessibility and affordability of immersion cooling systems make immersion cooling an attractive option for system cooling.

However, existing information processing systems that were originally designed for air cooling may not be well optimized for immersion cooling. In general, an air-cooled system can be relatively easily converted to a state in which it can be used in an immersion cooling tank, for example by removing the air-cooling specific components, such as fans, heat sinks, and baffles, as well as by removing components incompatible with immersion, such as thermal pasts, stickers, or the like. This form of conversion may be referred to herein as a baseline conversion because it represents a minimal conversion to ready the system for immersion. While the aforementioned baseline conversion can relatively easily allow for an air-cooled system to be converted for use in the immersion cooling tank, the resulting system is not well optimized for immersion cooling and thus some of the benefits which may be possible with immersion cooling may not be fully realized. For example, it may be desirable to provide additional cooling to certain components, such as a CPU, beyond the cooling that occurs when the system which has been converted in the manner described above is immersed in an immersion tank.

To address these and other issues, examples disclosed herein relate to an immersion cooling manifold module that can be mounted to a latch structure which is coupled to, or part of, the chassis, with the manifold outside of a chassis of the system (e.g., adjacent a front or rear panel). The latch structure may, for example, be part of a rail assembly coupled to the chassis. In some examples, the latch structure is a cable management arm (CMA) latch point.

When the immersion cooling manifold module is mounted to the latch structure, the manifold module is configured to draw in liquid coolant from the pool outside the chassis and generate flow of the liquid coolant directed into the chassis (e.g., through the front or rear panel), thereby creating, or strengthening, a bulk movement of liquid through the chassis. This forced convection through the chassis improves cooling of the electronic components therein. The improved cooling performance may allow for reduced operating temperatures of components, which can improve their own power efficiencies and reduce wear and degradation, potentially increasing their lifetime. In particular, in some examples, although a pump which creates the forced convection does consume some power, the power savings created by reducing the operating temperatures of the electronic components of the system may more than offset the power consumption of the pump, creating a net power saving. The improved cooling performance may additionally or alternatively allow for increasing system performance parameters (e.g., CPU frequency) to achieve greater system performance while maintaining previous temperatures. Furthermore, in some examples, the power draw and noise generated by the pump may be much less than the noise and power draw which would be associated with achieving similar cooling performance using air cooling, thus allowing for immersion cooling to remain the more efficient cooling approach.

In some examples, the manifold module is positioned outside a rear panel of the chassis so that the bulk movement of liquid through the chassis created by the manifold flows in a rear-to-front direction. This arrangement may be particularly useful in immersion cooling tanks which have a cooler end (e.g., bottom) and a warmer end (e.g., top) and in which the information processing systems are oriented with their rear panels adjacent the cooler end of the tank, as in such cases the manifold can draw in cooler liquid, which further improves cooling. In other examples, the manifold module is positioned outside a front panel of the chassis so that the bulk movement of the liquid through the chassis flows in a front-to-rear direction. This arrangement may be useful in immersion cooling tanks where the information processing systems are oriented with their front panels adjacent the cooler end of the tank.

In some examples, the manifold module comprises a manifold and a set of mounting arms coupled to opposite ends of the manifold, with each of the arms being configured to releasably mount to a corresponding rail of the rail assembly. In some examples, the mounting arms may be hingedly coupled to a manifold. Each mounting arm may include a latch to engage with a latch structure coupled to or formed as part of the chassis. In some examples, the latch structure may be part of a rail assembly coupled to the chassis, with the latch structure coupled to or formed as part of the rail assembly. In some examples, the latch structure may be a latch structure configured to receive a cable management arm (CMA) mounted thereto (hereinafter, “CMA latch point”). In an air-cooled system which is configured for mounting to a rack via a rail assembly, the CMA may be used to support and organize external cables (e.g., power cables, communication cables, etc.) plugged into the system while facilitating the sliding of the system into and out of the rack along rails of the rail assembly. The CMA latch points are coupled to (or part of) the rail assembly and/or the chassis and are configured to mate with corresponding latching features of the CMA to mount the CMA. But in an immersion cooling system, a CMA can often be omitted, in which case the manifold can be coupled to the CMA latch points in lieu of a CMA. Thus, in such examples, the latches at the ends of the mounting arms may be configured to be complementary to the CMA latch points to allow for mounting thereto. In particular, the latches may have a configuration which mimics the latches found on CMAs. The ability to mount to the CMA latch points allows for an existing structure originally designed for mounting a different device (the CMA) to be repurposed for mounting the manifold module to the system, thus avoiding the cost and complexity of designing and producing a new chassis with a dedicated latch structure for mounting the manifold module. Furthermore, the repurposing of these CMA latch points for mounting the manifold module can make field upgrade or retrofitting of existing systems easier and more cost effective, as the CMA latch points are already present in many systems and, even when not present, they can be easily acquired and added to a system.

The manifold includes a manifold body, an interior chamber within the manifold body, a fluid inlet, and a plurality of fluid outlets. The inlet and the outlets comprise openings through the manifold body which are fluidically coupled to the interior chamber, such that liquid can enter the interior chamber of the manifold via the inlet and exit the interior chamber via the outlets. The inlet may also include, in some instances, a liquid coupling device (such as a hose-barb, threaded coupling, quick-disconnect (QD) coupling, etc.) to allow for a liquid conduit to be connected to the inlet. The outlets may include, in some instances, nozzles fluidically coupled to the outlet openings to guide and/or increase the velocity of the output streams. The outlets may be arranged such that, when the manifold is mounted to the rails, the outlets expel the liquid coolant as multiple output streams which are directed towards and into the chassis of the information processing system (e.g., through the front or rear panel, depending on the mounting position of the manifold).

A pump may be fluidically coupled to the inlet via a liquid conduit (e.g., tube) and configured to draw in liquid coolant from the immersion tank and force the liquid through the manifold, thereby generating the output streams which are expelled from the outlets. In some examples, the manifold module includes the pump as a part thereof, with the pump being attached to the manifold. For example, a pump mounting bracket may be coupled to the manifold body adjacent to the fluid inlet. The pump mounting bracket may removably receive and hold a pump, which may then be coupled to the fluid inlet of the manifold to move fluid through the manifold body and out the fluid outlets. In some examples, the pump mounting bracket may include a ring structure with an aperture defined therein such that part of the pump may be disposed within the aperture with the ring structure surrounding and holding the pump therein. The ring structure may include a friction feature, such as a rubber pad, to increase the static friction between the pump and the ring structure and assist in retaining the pump within the pump mounting brackets. In some of these examples, the ring structure may be capable of selectively being opened and/or increasing in diameter to allow for insertion of the pump into the aperture and then being selectively closed and/or decreasing in diameter to allow the ring structure to engage and hold the pump. For example, the ring structure may include a hinged portion which can be pivoted about the hinge to open or close the ring structure. As another example, the ring structure may include an elastically deformable portion which is deflectable to allow the brackets to be opened and/or to increase in diameter to receive a pump and to return to their previous state to close around the pump when the pump is installed. Once installed, the pump may be coupled to a power supply on the system board, allowing the pump to circulate coolant fluid through the manifold such that fluid is moved over electronic components installed on the system board. The coolant fluid may be drawn from an immersion pool directly by the pump or may be moved to the pump via a hose coupled to the pump, with the coolant fluid being drawn from a coolant distribution unit.

As mentioned above, in some examples, a fluid outlet may include, in addition to an outlet opening, a nozzle coupled to the manifold body and fluidically coupled with the outlet opening. In some examples, these nozzles may be removably coupled to the outlet openings, for example via threading or other means. A nozzle, when installed in a fluid outlet, may increase the speed with which the coolant fluid is ejected and/or focus the stream. Such an outlet which has a nozzle may be referred to as a nozzle outlet. In some examples, only some of the outlets are nozzle outlets, and other outlets may lack a nozzle. In some cases, an outlet that lacks a nozzle may instead include a removable plug, which is coupled to the manifold body at the outlet opening, in some cases using the same attachment means as would be used by a nozzle. A plug, when installed in a fluid outlet prevents fluid from exiting the manifold at the blocked fluid outlet. Such an outlet which has a plug may be referred to as a plugged outlet. Together, the use of removable nozzles and plugs may allow a system manufacturer, or a user, to refine how the flows of coolant are distributed through the chassis. For example, if it is desired to concentrate the flows of coolant in a particular region (or regions) of the chassis (e.g., allowing coolant fluid to be directed over specific electronic components), then this could be achieved by providing outlets aligned with the region (or regions) with nozzles while providing the remaining outlets which are not aligned with the region (or regions) with plugs (or with a smaller concentration of nozzles).

Furthermore, in some examples, different nozzles having different parameters (e.g., different internal diameters) may have different flow rates or different stream velocities, and in some examples the distribution of liquid flows through the system may be refined by selecting appropriate nozzles for the various outlets. This may include, in some cases, providing different nozzles to different outlets so that the output streams from these outlets have different characteristics (e.g., different flow rates, etc.). This can allow for another layer of flow refinement, in addition to or in lieu of using plugs. For example, if it is desired to provide liquid flows throughout the entire chassis, but to concentrate higher flow rates in a certain region, then nozzles may be provided to outlets across the full width of the chassis, but the outlets aligned with the given region may be provided with nozzles having higher flow rates than those provided to the other outlets.

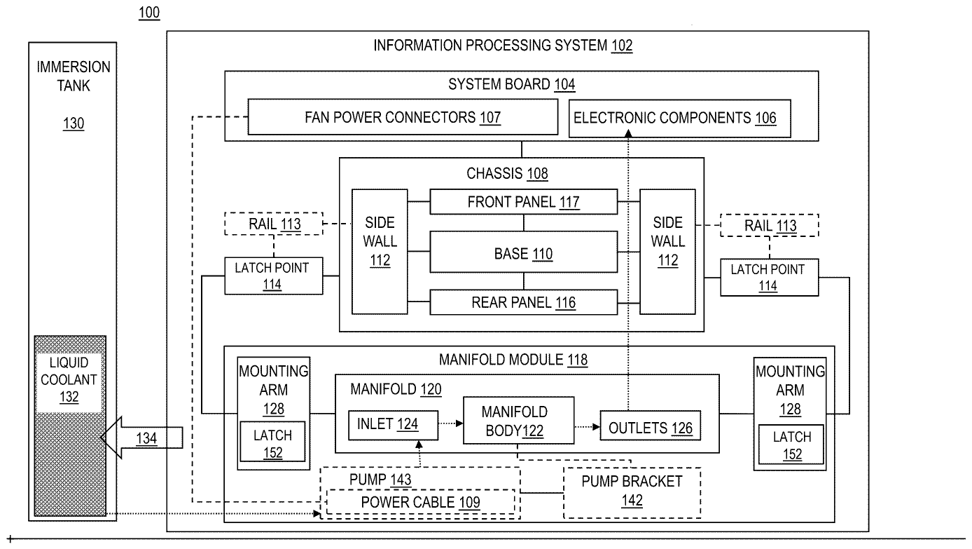

These and other examples will be described in greater detail below in relation to FIGS. 1-10.

FIG. 1 illustrates an example system 100. FIG. 1 is schematic in nature, and it should be understood that FIG. 1 is not intended to illustrate specific shapes, dimensions, positional relationships, or other structural details accurately or to scale, unless otherwise noted herein. Implementations of information processing system 100 may have different numbers and arrangements of the illustrated components. In addition, components illustrated in FIG. 1 may be omitted from some examples disclosed herein, and components which are not illustrated in FIG. 1 may also be included in some examples disclosed herein. In FIG. 1, physical connections (e.g. physical attachment and/or support) between components are indicated conceptually by solid lines extending between the components. Certain positional relationships are indicated by thick, white-filled arrows. Motion of coolant is indicated by dotted-line arrows. Certain components and connections which are optional (i.e., included in some, but not necessarily in all, examples) are depicted in FIG. 1 using dashed lines (note that the explicit identification herein of some aspects as being “optional” does not imply that other aspects not so identified are not optional).

System 100 is a system for immersion cooling information processing devices, such as servers, networking devices, or the like. System 100 includes an information processing system 102 and an immersion tank 130. The immersion tank 130 contains a pool of liquid coolant 132 and is configured to receive multiple information processing systems immersed in that coolant 132 to provide immersion cooling thereto, as will be explained in greater detail below.

Information processing system 102 may be a server, a networking device (e.g., switch, router, etc.), or other device with information processing components. Information processing system 102 may include a system board 104, a chassis 108, and a manifold module 118.

Chassis 108 may include structural components to support and/or house other components of the system 102. The chassis 104 may include base 104 and a rear panel 116. A pair of side walls 112 may be coupled to base 110 and to rear panel 116. Side walls 112 may be disposed generally parallel to one another such that the side walls 112 are separated by the base 110. Other structural members, such as a front panel and/or a cover may be coupled together to define an interior volume in which other components of the system are housed. The chassis may also include other support structures, which may be disposed in or form integral parts of the aforementioned housing, such as drive cages, power supply unit cages, etc. In lieu of forming a housing, chassis 108 may alternatively include a tray or other support structure which supports, but does not necessarily fully enclose, the components of the system.

The system 102 also comprises one or more latch points 114, which are coupled to, or formed as part of, the chassis 108. The latch points 114 comprise latching structures configured to engage with a complementary latch of a device (e.g., latches 152 of manifold module 118, described below) to mount the device to the chassis 108. In some examples, the latch points 114 comprise CMA latch points, which are configured to be capable of receiving and mating with latches of a CMA to mount the CMA to the chassis 108. In some examples, one (or both) of the latch points 114 may be coupled to, or formed as part of, the side walls 112. In some examples, one (or both) of the latch points 114 may be coupled to, or formed as part of, the rear panel 116. In some examples, one (or both) of the latch points 114 may be coupled to the front panel 117. In some examples in which rails 113 are included, one (or both) of the latch points 114 may be coupled to, or formed as part of, rails 113.

The system board 104 may be supported by chassis 108. The system board 104 may be a motherboard that includes electronic components 106 coupled thereto. Electronic components 106 include at least some information processing components, such as a central processing unit (CPU), a memory, or the like, as well as other passive or active electrical components (not illustrated), but examples are not so limited and any system board may be used. In some examples, system 102 is compatible with both air-cooling and immersion cooling, meaning that system 102 is switchable between an air-cooled configuration and an immersion cooled configuration. In such examples, system board 104 may include fan power connectors 107 to mate with fan power cables of fans when system 102 is being air-cooled.

The manifold module 118 may be coupled to chassis 108 by the latch points 114. Manifold module 118 includes a manifold 120 and one or more mounting arms 128, such as a pair of mounting arms, coupled thereto and configured to mount the manifold 120 to the latch points 114. The manifold module 118 may also include pump brackets 142 to mount a pump to the manifold 120, as well as a pump 143 in some examples. The manifold module 118 is configured to, when mounted to the latch points 114 and when the system 102 is immersed in the immersion tank 130, draw in liquid coolant 132 from the pool outside the chassis 108 and output streams of the liquid coolant 132 which are directed to flow into and through the chassis 108 (e.g., via the rear panel 116 or front panel 117, depending on the example), thus improving the rate at which the information processing system 102 is cooled as compared to immersion cooling without the manifold module 118.

As used herein, a manifold refers to a structure that receives a liquid input and distributes the input to multiple outputs. Manifold 120 comprises a manifold body 122, a fluid inlet 124, and multiple outlets 126. Manifold body 122 may be hollow, defining an interior chamber through which a coolant liquid can flow. The fluid inlet 124 and fluid outlets 126 comprise holes (e.g., openings) through one or more outer walls of the manifold body 122 which fluidically connect the interior chamber with the environment outside the manifold body 122. In some examples, the fluid inlet 124 and/or outlets 126 comprise just the aforementioned holes through the manifold body 122. In other examples, the fluid inlet 124 and/or fluid outlets 126 may also comprise additional structures, which are fluidically coupled with the interior chamber via the holes. For instance, in some examples, some or all of the fluid outlets 126 may include nozzles. In some examples, fluid inlet 124 may include an intake fluid coupling (e.g., a friction-fit fluid coupling, a hose barb, a threaded fitting, a compression fitting, etc.) which can couple with a tube or pipe, although examples are not so limited. More particularly, the fluid inlet 124 may comprise one half of such a fluid coupling when the fluid coupling comprises two mating halves. In some examples, fluid inlet 124 may also include an inlet pipe which may be integrally formed with manifold body 122 and allows manifold body 122 to be fluidically coupled with a pump; however, examples are not so limited. In examples in which the inlet 124 and/or outlet 126 include additional structures (such as nozzles or fluid couplings), these may be integrally formed with the manifold body 122 or may be separately formed parts which are coupled to manifold body 122.

A pump 143 may be fluidically coupled to the inlet 124 of the manifold 120 via a liquid conduit (e.g., a tube, pipe, etc.) to drive the flows of liquid through the manifold 120. In some examples, the pump 143 is part of the manifold module 118 and is physically attached to the manifold 120. Pump 143 may include a power cable 109 that supplies electrical power and/or data signals to the pump 143. In some examples, the power cable 109 may be connected to one of the fan power connectors 107 (e.g., power supply connectors) on the system board 104. In such examples, instead of system board 104 supplying fan driving signals to a fan via fan power connectors 107, system board 104 may instead be configured to supply pump driving signals to the pump 143 via fan power connectors 107 to supply power and/or otherwise control operations of the pump 143.

In some examples, at least one pump bracket 142 may be coupled to manifold body 122. Pump bracket 142 may be configured to selectively receive a pump 143 coupled to manifold 120. Pump bracket 142 may be integrally formed with manifold body 122 or may be formed separately and coupled to manifold body 122. In some examples, pump bracket 142 may be located on an opposite side of the manifold body 122 from the outlets 126, to avoid interference with their outputs. In some examples, the pump brackets 142 may be disposed adjacent to inlet 124, to allow easier fluid connection between a pump 143 and inlet 124 when the pump 143 is coupled to bracket 142. In other examples, while the pump 143 is fluidically coupled to the inlet 124, the pump 143 is not necessarily part of the manifold module 118 and is not directly coupled to the manifold 120.

Manifold module 118 further includes one or more mounting arms 128. Mounting arms 128 may be coupled to manifold body 122 such that manifold arms 128 extend away from manifold body 122. The mounting arms 128 may be coupled to opposite end portions of the manifold body 122. In some examples, mounting arms 128 extend from manifold body 122 in directions transverse to a first dimension of the manifold body 122, wherein the first dimension extends between the aforementioned end portions of the body 122. In some examples, the first dimension is a longitudinal (i.e., longest) dimension of the manifold body 122, which is also the dimension along which the outlets 126 are arrayed across the manifold body 122. In examples in which the manifold body 122 has a tube shape with a central axis, the first dimension is parallel to the central axis. In some examples, mounting arms 128, or a portion thereof, may be integrally formed with manifold body 122, such that manifold body 122 and mounting arms 128 (or the portion thereof) are a single monolithic (i.e., continuous, unitary) body. For example, the manifold body 122 and mounting arms 128 (or portion thereof) may be integrally formed together by injection molding, casting, additive manufacturing (e.g., 3D printing), subtractive manufacturing (e.g., machining), or the like. In other examples, mounting arms 128 and manifold body 120 may be formed as separate parts and the mounting arms 128 may be coupled to manifold body 122 by mechanical fasteners, adhesives, welding, heat staking, friction fitting, or any other joining techniques. In some such examples, mounting arms 128 may be coupled to manifold body 122 by engagement of a pivotable attachment to allow mounting arms 128 to pivot with respect to manifold body 122. In such examples, manifold arms 128 may be movable with respect to manifold body 122 during installation of manifold module 118 onto chassis 108.

Each mounting arm 128 may include a latch 128. Latch 128 may be configured to engage with a latch point 114 on side wall 112 of chassis 108. Thus, the latch points 114 are configured with latching features which are complementary to those of the latch points 114. In examples where the latch points 114 comprise CMA latch points, the latches 128 may have features which mimic those of a latch of a CMA. When latches 128 are coupled to latch points 114, the first dimension of the manifold 120 is disposed generally parallel to rear panel 116 or front panel 117 (depending on the example), with outlets 126 facing towards the interior of the chassis 108 (i.e., through the rear panel 116 or front panel 117) and, ultimately, the electronic components 106 therein. References to the outlets 126 facing towards something should be understood as the outlets 126 being oriented such that the streams of liquid ejected thereby are directed towards the thing faced. In some examples, when the latches 128 are coupled to latch points 114, and inlet 124 faces away from chassis 108.

System 100 may further include an immersion tank 130 including liquid coolant 132 held in a liquid-holding portion of the tank 130 to create a pool of liquid coolant 132. The liquid-holding portion of the tank 130 may be configured to receive information processing system 102 such that information processing system 102 is immersed in the pool of liquid coolant 132. As used herein, “immersed” means that at least the system board 104 is submerged in the liquid coolant 132. In some examples, the entirety of each information processing system 102 may be fully submerged. In other examples, a small portion of a system 102, such as a support bracket which supports the system, may protrude out of the liquid coolant 132. The immersion of system 102 in the liquid coolant 132 is shown by arrow 134.

The coolant 134 may be an electrically non-conducting material that is liquid at room temperatures, such as dielectric fluid. Immersion of information processing system 102 into liquid coolant 134 allows heat generated by electronic components 106 to be removed from the information processing system 102. More particularly, the coolant 132 absorbs heat from components of the system, via convection, and releases the heat externally from the system. In some examples, the coolant 132 may be a single-phase coolant, meaning it is engineered to absorb heat and circulate it through the immersion tank 130. This circulation may include transferring the absorbed heat to a heat exchanger (not shown in FIG. 1) before being circulated back through the immersion tank 130, thus allowing liquid coolant 132 to be continually moved over the information processing system 102. In other examples, the coolant 132 is a two-phase coolant, meaning it is engineered to transport heat by changing between liquid and vapor (gas) phases during operation of the device. In such examples, the coolant 132 has a boiling point which is near a desired operating temperature of the electronic components 106, which means that the electronic components 106 can bring the coolant 132 to boiling during operation. This boiling absorbs heat from the components and allows the heat to be dissipated via interaction of coolant 132, in vapor form, with a heat sink or other heat dissipating structures (not shown).

When information processing system 102 is immersed in liquid coolant 132, manifold 120 may be configured to generate flows of the liquid coolant 132 through system 102. More particularly, pump 143 may draw liquid coolant 132 from the pool in the immersion tank 130 and provide that liquid coolant 132 to the fluid inlet 124 of manifold 120, and the inlet 124 conveys that liquid coolant 132 into the interior chamber of the manifold body 122. The liquid coolant 132 then flows through manifold body 122 before flowing through outlets 126 of manifold 120 back out into the pool of liquid as multiple output streams. In some examples, fluid outlets 126 may direct liquid coolant 132 over electronic components 106 on system board 104. More particularly, fluid outlets 126 may be oriented to flow over selected electronic components 106. For example, fluid outlets 126 may be positioned to allow liquid coolant 132 to flow over high-temperature components, such as a CPU or a memory, thus allowing additional liquid coolant 132 to be moved over components, increasing the cooling of these components. Before reaching these electronic components 106, the output streams may first enter the chassis 108 by passing through the rear panel 116 or the front panel 117 (depending on example). In some examples, the output streams may provide a bulk movement of liquid through the chassis 108, which improves cooling of all electronic components therein, as opposed to being narrowly targeted at cooling particular components 106. In some examples, the flow of liquid can be tailored to favor some regions of the chassis 108 (e.g., regions with greater heat density) with more (or with swifter) flows of liquid to improve cooling in those regions. This tailoring may be done by controlling the positioning and/or configuration of the outlets 126, such that a greater density of outlets 126 is provided in some portions of the manifold body 122 than others and/or outlet 126 with different flow characteristics are provided in different portions of the manifold body 122, thus allowing some regions to receive more of the output streams and/or output streams with greater flow rates than others. In some examples, the manifold 120 is configured to allow for this tailoring to be changed post manufacture, such as by selectively adding, moving, replacing, or removing nozzles from the outlets 126 and/or plugging outlets 126. In this manner, while the manifold 120 may still provide a bulk flow of liquid through the chassis, this flow may be more concentrated (have a higher flow rate) in some regions than it is in others.

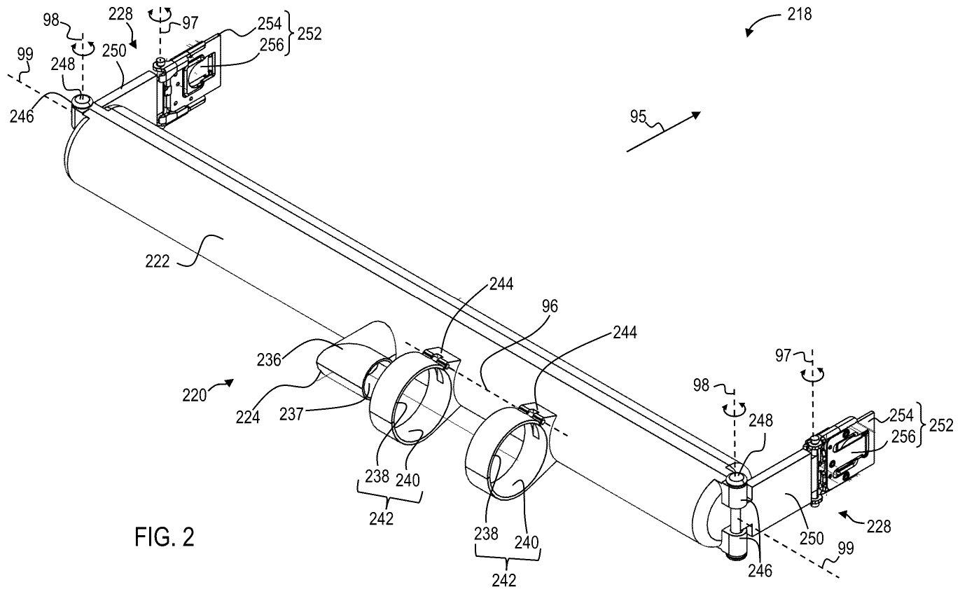

Turning to FIGS. 2-6, an example manifold module 218 is shown. Manifold module 218 may be one implementation of an example manifold module 118, shown in and described with respect to FIG. 1, and may be used in a system such as system 100, described with respect to FIG. 1. Manifold module 218 thus comprises components which correspond to (i.e., are implementation examples of) components of the manifold module 118, and the correspondence between such components is indicated herein by the components having references numbers with the same last two digits, such as 122 and 222. Aspects of the manifold module 118 and its components described above may also be applicable to the manifold module 218 and its corresponding components, but the manifold module 118 and its components are not limited to the manifold module 218 and its components, which are just one example of how the manifold module 118 may be implemented. In some instances, aspects of the manifold module 118 already described above, which are also applicable to the manifold module 218, are not described below to avoid duplicative description.

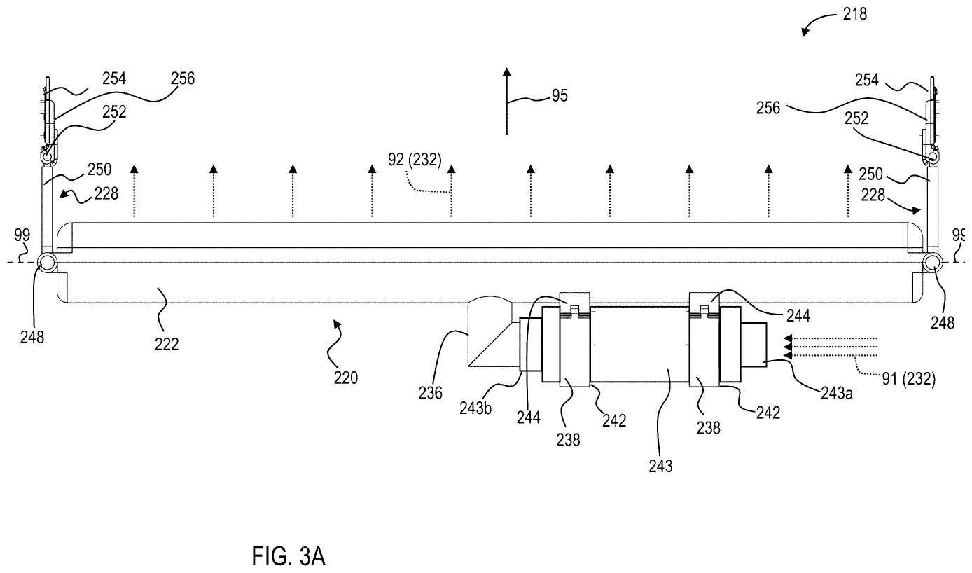

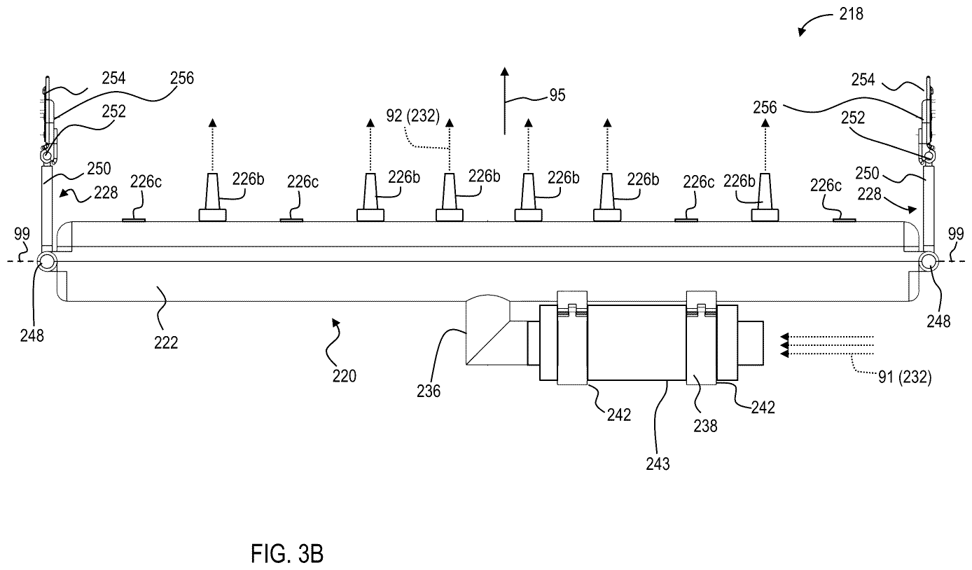

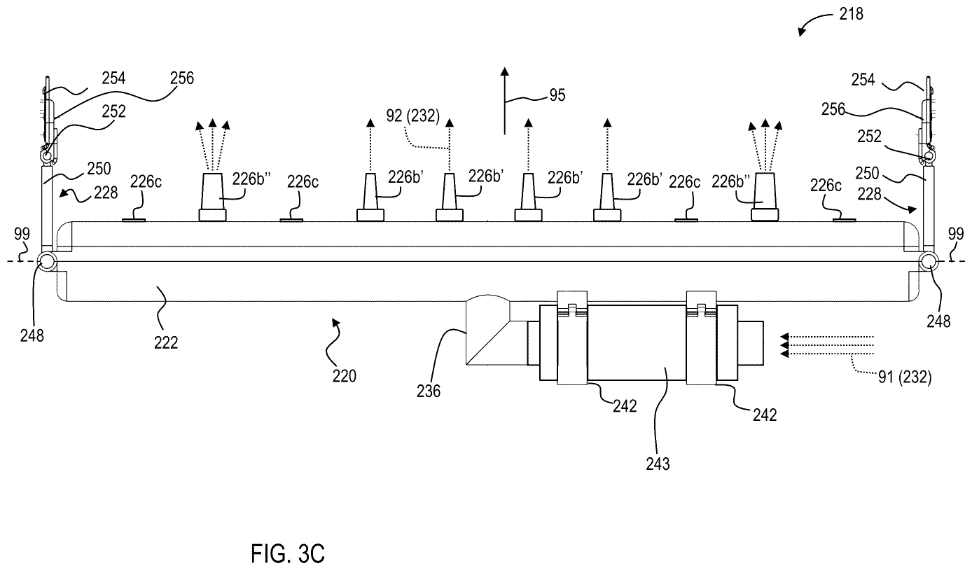

Manifold module 218 includes a manifold 220, a pair of mounting arms 228, and pump brackets 242 (“brackets 242”). In some examples, manifold module 218 also includes a pump 243, as shown in FIG. 3, while in other examples pump 243 is omitted or provided separately.

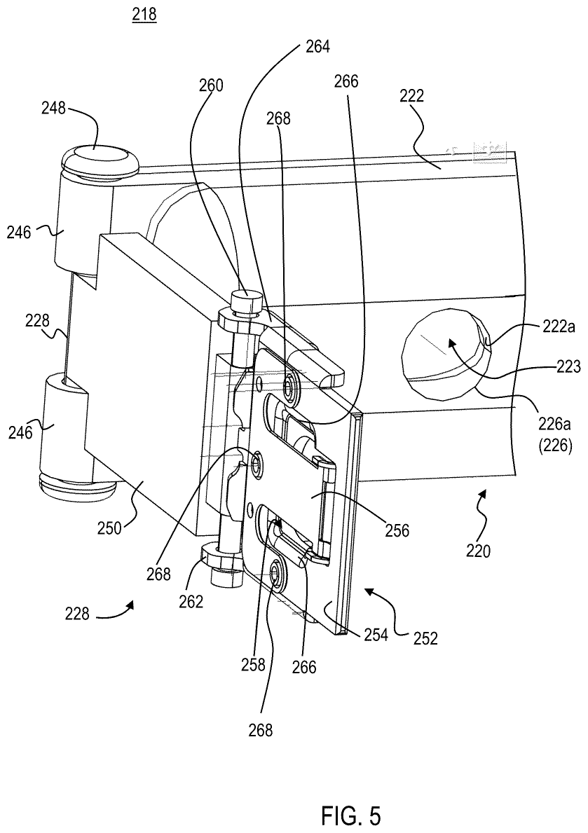

Manifold 220 includes a manifold body 222. The manifold body 222 is hollow and defines an interior chamber 223 (partially visible in FIG. 5) to allow fluid, such as liquid coolant, to flow through the manifold 220. More specifically, as shown in FIG. 2, in this example the manifold body 222 has a shape like a tube (also referred to as a hollow cylinder, cylindrical shell, or the like) with the two ends of the tube being closed. This tube-like manifold body 222 has a central axis 99, which also happens to be parallel to a longitudinal dimension of the manifold body 222.

A fluid inlet 224 is coupled to manifold body 222 and fluidically coupled to the interior chamber 223 thereof. Fluid inlet 224 includes a hole (not visible in the figures) through an outer wall of the manifold body 222 and an inlet pipe 236 attached to manifold body 222 over the hole. The inlet pipe is hollow and has an opening 237 formed in a distal end of the inlet pipe 236 which allows liquid coolant to flow into inlet pipe 236. Inlet pipe 236 further has another opening (not visible) in a proximal end which covers the hole in the manifold body 222 such that the interior of the inlet pipe 236 is communicably connected to the interior chamber 223 via this opening and the hole. Thus, liquid can flow from an exterior environment into the interior chamber 223 of manifold body 222 via the inlet 224.

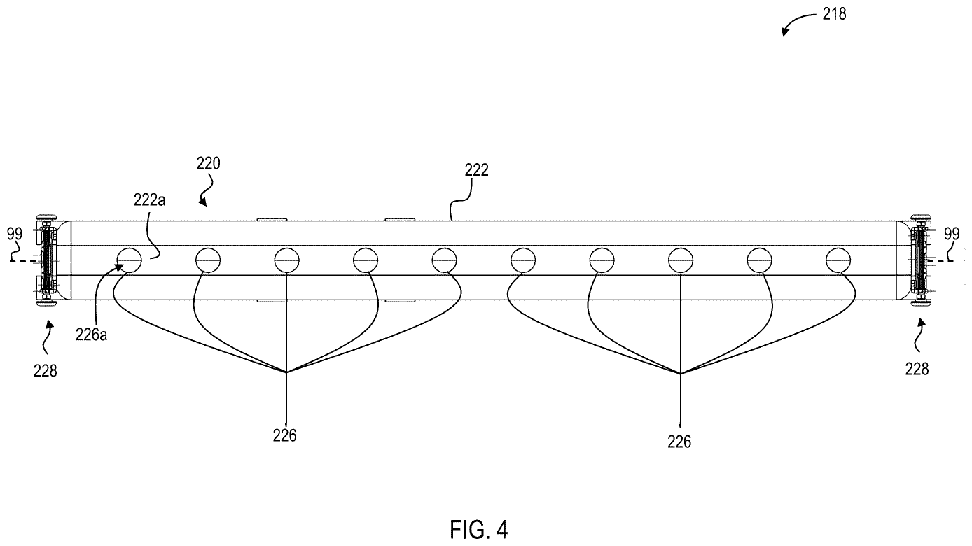

Manifold 220 further includes a plurality of fluid outlets 226. As shown particularly in FIGS. 4 and 5, fluid outlets 226 comprise outlet openings 226a through a wall 222a of manifold body 222, which communicably connect the internal chamber 223 with an external environment. The fluid outlets 226 are formed in/on a side of the manifold body 222 which will face the chassis of an information processing device when the manifold module 218 is mounted thereto, i.e., they are disposed in a side of the manifold body 222 facing along the direction 95 indicated in FIG. 3. The fluid outlets 226 are arrayed in a line parallel to the central axis 99. The fluid outlets 226 are configured to expel output streams 92 of liquid coolant 232 (depicted in FIGS. 3A and 3B as dotted-line arrows), and the outlets 226 are oriented to direct these output streams 92 of liquid coolant 232 outward from manifold body 222 along directions transverse to axis 99 of manifold body 222, i.e., parallel to the direction 95 indicated in FIGS. 3A and 3B. When the manifold module 218 is mounted to an information processing device, the direction 95 points towards the front panel of the chassis thereof if module 218 is mounted adjacent the front panel or toward the rear panel of the chassis if module 218 is mounted adjacent the rear panel, and therefore the output streams 92 are directed towards the front or rear panel, as will be discussed below. Furthermore, when the manifold module 218 is mounted to the information processing device, the central axis 99 may be parallel to a width dimension of the device and the manifold module 218 may extend across this width dimension from one side wall of the chassis to the other, and therefore the output streams 92 may be distributed across the width dimension of the device. The fluid outlets 226 may be oriented to direct fluid over particular electronic components.

While ten fluid outlets 226 are shown in FIG. 4, examples are not so limited, and more or fewer fluid outlets 226 may be used. In addition, although fluid outlets 226 are shown disposed linearly along a central axis 99 of the manifold body 222, fluid outlets 226 may be disposed elsewhere on the manifold body 228 and in other orientations with respect to the central axis 99 of manifold body 228.

In some examples, at least one of the fluid outlets 226 is a nozzle outlet which comprises both an outlet opening 226a and a nozzle 226b, as illustrated in FIG. 3B. The nozzle 226b may, in some examples, be selectively (e.g., reversibly) attached to the outlet opening 226a by, e.g., threading. The nozzles 226b may allow the output streams 92 to be more focused, have higher velocities, or otherwise produce desired flow characteristics. In some examples, at least one of the fluid outlets 226 may include a removable plug 226c inserted into or over the outlet opening 226a of the fluid outlet 226 to block the outlet opening 226a and prevent movement of a fluid through the plugged outlet opening 226a. By modifying the fluid outlets 226 using selectively installed nozzles 226b and/or plugs 226c, manifold 220 can be adapted to produce different patterns of output streams 92 based on cooling needs of a system.

For example, as shown in FIG. 3B, in one possible configuration the outlets 226 are provided with a greater concentration of nozzles 226b in a center region of the manifold 220 and with a greater concentration of plugs 226c in peripheral regions, which results in a greater concentration of output streams 92 in the center region. This may be desired, for example, when the center region of an information processing device is expected to have hotter components which may benefit from higher flow rates while peripheral regions are expected to require lesser flow rates. Of course, the pattern illustrated in FIG. 3B is just one example and any other desired combination of nozzles 226b and plugs 226c could be used to achieve various other desired flow pattern, according to the particular needs of the system in which the module 218 is installed. Moreover, in cases where the nozzles 226b are removable, the module 218 could be reconfigured after manufacture, for example if the needs of the system change, by adding, removing, or moving the nozzles 226b.

In addition to affecting the overall flow patterns by selecting the numbers and arrangement of nozzles 226b and plugs 226c, the flow pattern can be further tuned by selecting the type of nozzle 226b that is used from among multiple possible types of nozzles. Different nozzles, which have different sizes, shapes, or other characteristics, may produce output streams having different flow characteristics. For example, a nozzle with a narrow inner diameter may produce a more focused output stream with higher velocity but may also present a higher flow impedance and lower flow rate (volume per unit time), in comparison to a nozzle with a wider inner diameter. Nozzle outlet shape can also vary from one type of nozzle to another and can affect the output stream characteristics, including by changing the cross-sectional shape, dispersion pattern, or other flow characteristics of the output stream. For example, a nozzle outlet with the shape of an elongated narrow slit may produce a stream which fans out laterally away from a central axis of the stream, progressively widening the stream the farther from the nozzle it gets, whereas a nozzle outlet with a circular shape may produce a more columnar stream. Furthermore, in some examples, different types of nozzles 226b are mixed together within the same manifold 220. For example, FIG. 3C illustrates a hypothetical configuration in which nozzles 226b′ of a first type and nozzles 226b″ of a second type are both used, with the nozzles 226b′ and nozzles 226b″ producing differently shaped output streams 92, as suggested by the dotted line arrows in FIG. 3C. Of course, this is just one example and any type of nozzle, or any combination of types of nozzles, may be used.

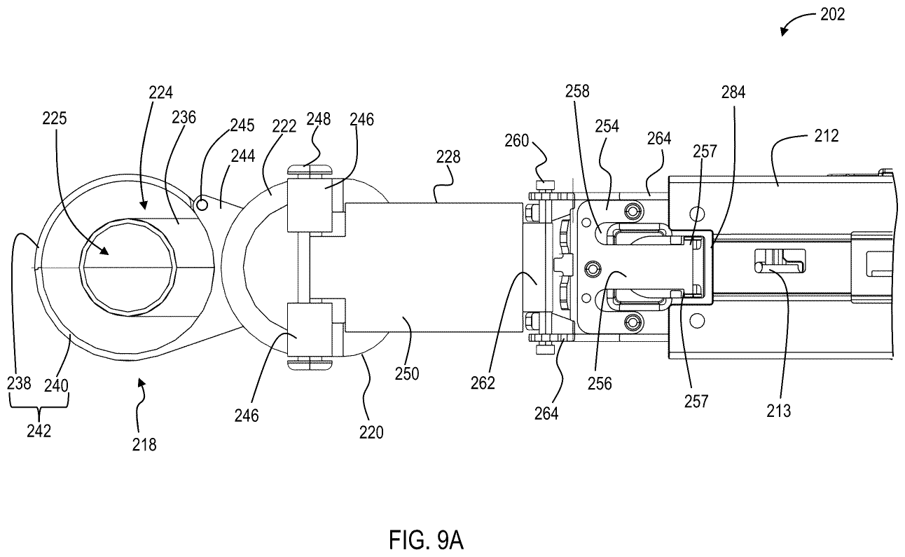

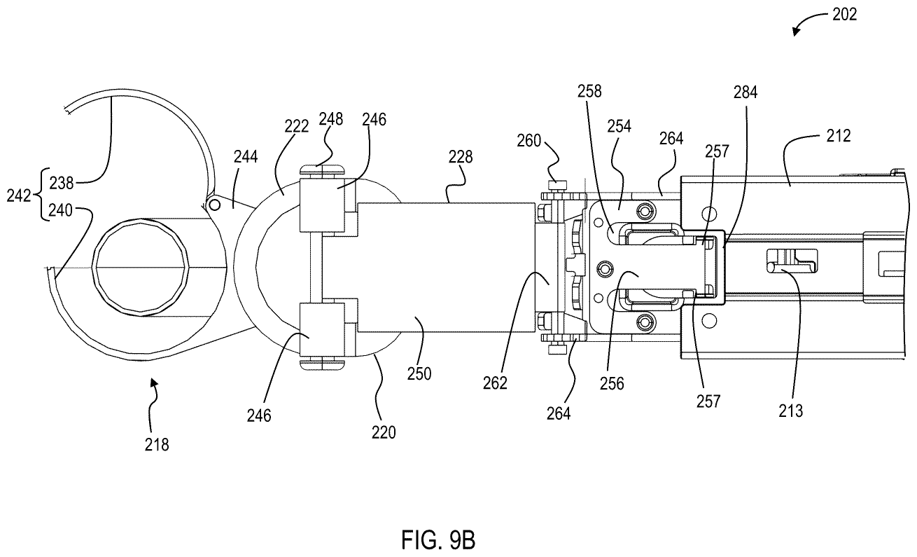

As shown in FIG. 2, pair of brackets 242 are coupled to manifold body 222. Each bracket 242 includes a semi-circular upper portion 238 and a semicircular lower portion 240. Upper portion 238 is pivotally attached to manifold body 222 at pivot attachment 244. Thus, upper portion 238 is able to pivot with respect to lower portion 240 between a closed state and an opened state in which a separation between upper portion 238 and lower portion 240 is increased. For example, FIG. 9A shows the closed state and FIG. 9B shows the open state of the brackets 242. Pivoting upper portion 238 to the opened state allows a pump 243 to be received within brackets 242, as shown in FIG. 3. An outlet 243b of pump 243 is coupled to inlet pipe 236 of fluid inlet 224 such that pump 243 is in fluid connection with opening 237. Once pump 243 is positioned and coupled to fluid inlet 224, upper portion 238 is released and returns to its closed position, allowing an edge of upper portion 238 to make contact with an edge of lower portion 240. In this state, the bracket 242 clamps around and holds the pump 243, as shown in FIG. 3A. Once the pump 243 is installed in this manner, and the system is immersed in an immersion cooling tank, the pump 243 can draw in, through an inlet 243a thereof, a flow 91 of liquid coolant 232 from the surrounding pool of liquid, output the liquid coolant 232 into the manifold 220 via inlet 224, and cause the outlets 225 to expel the liquid coolant 232 as output streams 92. The inlet 243a of pump 243 can be left unconnected to any other conduit to draw in liquid 232 from the immediate vicinity of the pump 243, or it can be couple to a liquid conduit (e.g., tube) which may extend elsewhere to allow for liquid to be drawn from a more remote location, if desired. Although not illustrated, in some examples bracket 242 may include latching features to help secure the bracket 242 in the closed state and/or to impart pressure to hold the pump 243 securely. For example, the latching feature may include a draw latch which comprises a catch, a latch arm, and a lever, and the catch may be attached to either upper portion 238 or lower portion 240 while the latch arm and lever are attached to the other of the lower portion 240 and the upper portion 238, such that engaging latch arm with catch pulls the lower portion 240 and upper portion 238 together (i.e., to the closed state).

Manifold module 218 further includes a pair of mounting arms 228. Each mounting arm 228 includes a beam 250 and a latch 252. Each mounting arm 228 is coupled to manifold body 222, with the pair of mounting arms 228 separated by manifold body 222. More particularly, as shown particularly in FIG. 5, manifold body 222 includes a hinge pin housing 246 configured to receive a hinge pin 248. Hinge pin 248 is configured to pass through hinge pin housing 246 and a corresponding opening in the beam 250 of a mounting arm 228 to hingedly (e.g., pivotably) couple mounting arms 228 to manifold body 222. Thus, mounting arm 228 may be movable with respect to manifold body 222 about hinge pin 248. More particularly, beam 250 of mounting arm 228 may be pivoted relative to manifold body 222 about pivot axis 98 (see FIG. 2), which may aid in installation of manifold module 218 to chassis 202. For instance, in installing the manifold module 218 to the chassis 202, pivoting beam 250 of mounting arm 228 may aid in aligning the latch 252 of the mounting arm 228 with a corresponding latch point of the chassis 202. More particularly, because mounting arms 228 is hingedly coupled to manifold body 222, mounting arms 228 may be moved outwardly from the chassis 202 when manifold module 218 is being installed, allowing alignment of the latch 252 with the corresponding latch point of the chassis 202.

As mentioned, beam 250 is coupled to manifold body 222 at hinge pin 248 such that beam 250 extends from manifold body 222. A latch 252 is coupled to beam 250. Latch 252 is coupled to beam 250 by a latch hinge pin 260 passing through a latch hinge pin housing 262 and beam 250 to allow pivotal movement of latch 252 with respect to beam 250 about pivot axis 97, as shown in FIG. 2.

Latch 252 comprises a latch plate 254 and a deflectable latch arm 256. Latch plate 254 is coupled to beam 250 at attachments 268. Attachments 268 may be, e.g., screws, pins, or another suitable coupling features. Latch plate 254 is further coupled to beam 250 at brackets 264. Brackets 264 engage with upper and lower edges of latch plate 254, with latch hinge pin housing 262 being integrally formed with brackets 264. As such, when latch hinge pin 260 is engaged with latch hinge pin housing 262 and latch plate 254 is engaged with brackets 264, latch plate 254 is pivotable with respect to beam 250.

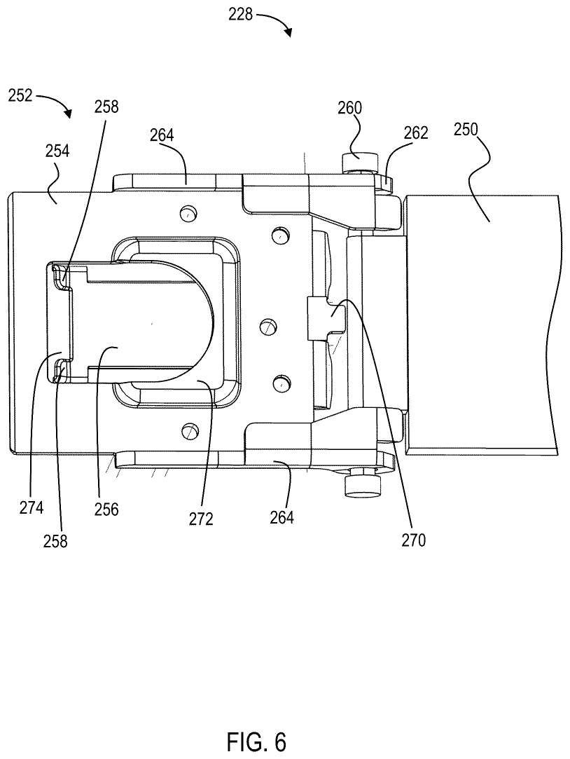

An opening 258 is formed in latch plate 254. As shown in FIG. 6, opening 258 is partially bounded by a plate holder 272 coupled to latch plate 254. A plurality of grasping tabs 266 are supported by plate holder 272 and extend through opening 258, as shown in FIG. 5. The grasping tabs 266 are configured to engage with corresponding features on a chassis, as described further herein.

A latch arm 256 is coupled to the latch plate 254 and extends into the opening 258, such that the latch arm 256 is accessible through the opening 258. Latch arm 256 is deflectable with respect to latch plate 254 to allow latch arm 256 to engage with a corresponding latch point. As shown in FIG. 6, latch arm 256 includes a tab 274 that is accessible through opening 258 and configured to engage with a corresponding attachment point when the latch arm 256 is engaged. A release tab 270 is located at the rear of the latch arm 256, adjacent to an edge of the latch plate 254. Release tab 270 is configured to selectively deflect latch arm 256 to allow disengagement of tab 274 when latch 250, and specifically latch arm 256, is in a coupled state with a latch point, as described further herein.

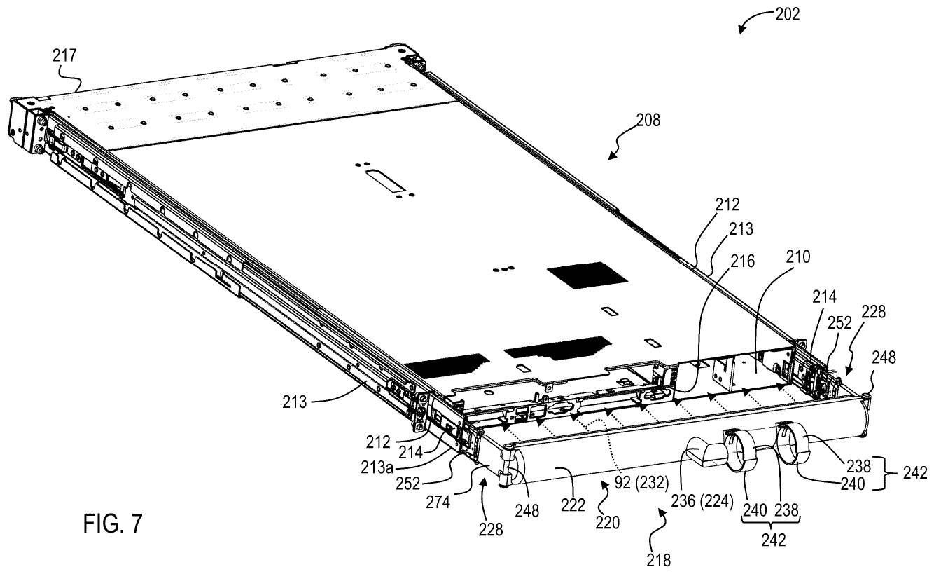

Turning to FIGS. 7-9, an example information processing system 202 in which the manifold module 218 described above may be used is shown. Information processing system 202 includes a chassis 208. Chassis 208 includes a base 210, a pair of side walls 212, a rear panel 216, a front panel 217, and a cover (not labeled). Chassis 208 supports a system board (not illustrated), which includes a plurality of electronic components (not illustrated). Electronic components may include a processor such as a CPU, a memory, storage drives, expansion cards (e.g. graphics processing units (GPUs), network interface cards (NICs), etc.) or any other information processing components.

Side walls 212 include rails 213 disposed along a length thereof. Latch points 214 are coupled to side walls 212 by rails 213. In some examples, latch points 214 are cable management arm (CMA) latch points. In such examples, latch points 214 are configured to removably engage with CMA latches to mount the CMA to the rails when information processing system 202 is in an air-cooled configuration. In an immersion cooled configuration, the latch points 214 are configured to instead engage with latches 214 of mounting arms 228 to mount manifold module 218 thereto in lieu of the CMA.

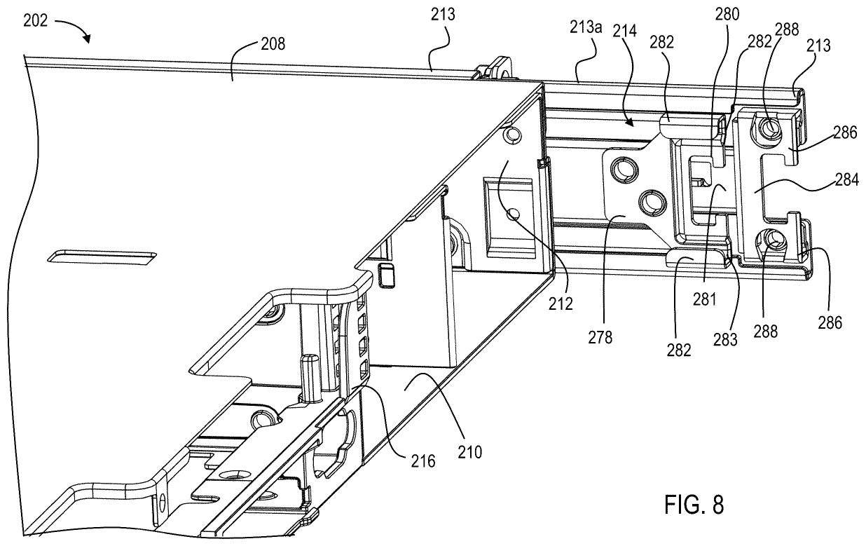

More particularly, each latch point 214 includes a CMA plate 278 coupled to side wall 212, as shown in FIG. 8. CMA plate 278 includes a first bracket 280 defining an opening 281, with the opening 281 configured to receive a latch arm such as latch arm 256. Opening 281 is bounded on an upper and lower edge by CMA tab 282, which extends out from first bracket 280, towards a center of chassis 208, and includes a vertical portion to define a space 281 between the tab 282 and the first bracket 280. CMA tab 282 is configured to receive and engage with corresponding tabs on latch 252. More particularly, CMA tab 282 is configured to receive grasping tabs 266, shown in FIG. 5, and to retain grasping tabs 266 within space 281.

Latch point 214 further includes a second bracket 284, with bracket 284 being located adjacent to first bracket 282 at an end of side arm 212. Second bracket 284 includes a pair of bracket arms 286 extending towards one another, with bracket arms 286 configured to engage with corresponding tabs on a latch arm 256 when the latch arm 256 is engaged with latch point 214. Second bracket 284 further includes attachment openings 288, which are configured to receive and engage with attachments 268 on latch 252 when latch 252 is engaged with latch point 214.

As mentioned above, latch arm 256 is deflectable with respect to latch plate 254 such that latch arm 256 can selectively engage with latch point 214. More particularly, as shown in FIG. 9, in an installed state, latch arm 256 engages with a second bracket 284 to hold latch arm 256 in an installed state. As described with respect to FIGS. 5 and 6, latch 252 includes additional components, such as grasping tabs 266, which are configured to engage with corresponding features on the latch point 214, as described with respect to FIG. 8. Thus, mounting arm 228 can be selectively coupled to chassis 208 at the side walls 212, allowing manifold module 218 to be mounted to chassis 208. As shown in FIG. 7 in particular, in the installed state, manifold module 218 is offset from the rear panel 216 of the chassis 208, with the outlets 226 on manifold 220 (not shown in FIG. 7) facing towards the rear panel 216, and more particularly towards electronic components disposed on system board.

When information processing system 202 is immersed in an immersion tank having a pool of liquid coolant, such as immersion tank 230 having liquid coolant 232, described with respect to FIG. 1, liquid coolant 232 is moved (by a pump, not shown in FIGS. 7-9) through fluid inlet 224 into and through the manifold 220 and then out of the outlets 226. The outlets 226 expel the liquid coolant 232 as output streams 92 which, in the example of FIGS. 7-9, are directed towards the rear panel 216, as indicated by the dotted line arrows in FIG. 7. These output streams 92 flow through the rear panel 216 into the interior of the chassis 208, eventually flowing over electronic components housed therein. Thus, when information processing system 202 is immersed in the liquid coolant to provide system cooling, certain electronic components are able to receive additional cooling, allowing information processing system 202 to remain at an operating temperature that is unlikely to cause heat-related damage to the system components. In addition, maintaining the information processing system 202 at an operating temperature allows electronic components to maintain ideal performance and avoid temperature-related throttling.

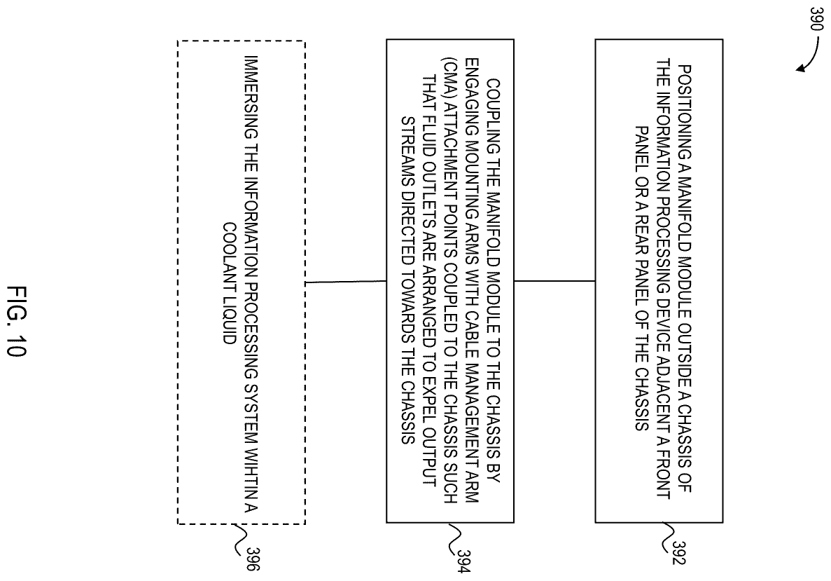

FIG. 10 is a method 390 for adapting an information processing system for immersion cooling. At 392, method 390 positioning a manifold module outside a chassis of the information processing device adjacent a front panel or a rear panel of the chassis. The manifold module comprises a manifold and mounting arms coupled to the manifold. For example, one of the manifold modules 118 or 218 described above may be used. In some examples, the method may include. as part of, or prior to, positioning the manifold module, removing a cable management arm (CMA) from the chassis. The CMA may have been coupled to CMA latch points prior to its removal. These CMA latch points are coupled to the chassis either direction or indirectly, such as via a rail coupled to the chassis. The cable management arm may be configured to support or otherwise receive cables in an air-cooled configuration of the system. Removal of the cable management arm allows the CMA latch points to become available for attachment of the manifold module.

At 394, method 390 includes coupling the manifold module to a chassis by engaging the mounting arms with the CMA attachment points, such that fluid outlets of the manifold are arranged to, on condition of a flow of liquid coolant being supplied to a fluid inlet of the manifold, expel output streams of the liquid coolant directed towards the chassis. If the manifold module was positioned adjacent the rear panel in step 392, the output streams may be directed towards, and flow into the chassis through, the rear panel. If the manifold module was positioned adjacent the front panel in step 392, the output streams may be directed towards, and flow into the chassis through, the front panel.

Coupling the manifold module to the chassis may further comprise coupling a pump to the manifold module. More particularly, the pump may be coupled to the manifold module at a plurality of brackets on the manifold module. Once the pump is coupled to the manifold module at the plurality of brackets, the pump may be coupled to a power supply on the system board. The power supply may be a power supply to which a fan connects in an air-cooled system and thus may be available for the pump to connect to while adapting the system to liquid cooling. The pump may then be fluidically coupled to a manifold within the manifold module. As described previously with respect to FIG. 3 in particular, the pump may be coupled to the manifold at a fluid intake, which may include a fluid intake valve.

At 396, method 390 may optionally include immersing the information processing system within a coolant liquid. More particularly, immersing the information processing system within a coolant liquid at 396 comprises immersing at least a portion of the system board including the immersion cooling adapter within the coolant liquid. This immersion allows coolant liquid to be moved to the manifold, providing cooling for components on the system board. In some examples, the coolant liquid is a dielectric liquid, although examples are not so limited.

It is to be understood that both the general description and the detailed description provide example implementations that are explanatory in nature and are intended to provide an understanding of the present disclosure without limiting the scope of the present disclosure. Other examples in accordance with the present disclosure will be apparent to those skilled in the art based on consideration of the disclosure herein. For example, various mechanical, compositional, structural, electronic, and operational changes may be made to the disclosed examples without departing from the scope of this disclosure, including for example the addition, removal, alteration, substitution, or rearrangement of elements of the disclosed examples, as would be apparent to one skilled in the art in consideration of the present disclosure. Moreover, it will be apparent to those skilled in the art that certain features or aspects of the present teachings may be utilized independently (even if they are disclosed together in some examples) or may be utilized together (even if disclosed in separate examples), whenever practical. In some instances, well-known circuits, structures, and techniques have not been shown or described in detail in order not to obscure the examples. Thus, the following claims are intended to be given their fullest breadth, including equivalents, under the applicable law, without being limited to the examples disclosed herein.

References herein to examples, implementations, or other similar references should be understood as referring to prophetic or hypothetical examples, rather than to devices/systems that have been actually produced, unless explicitly indicated otherwise. Similarly, references to qualities or characteristics of examples should be understood as representing the educated estimates or expectations of the inventors based on their understanding of the relevant principles involved, application of theory and/or modeling, and/or past experiences, rather than as being representations of the actual qualities or characteristics of an actually produced device/system or the empirical results of tests actually carried out, unless explicitly indicated otherwise.

Further, spatial, positional, and relational terminology used herein is chosen to aid the reader in understanding examples of the invention but is not intended to limit the invention to a particular reference frame, orientation, or positional relationship. For example, spatial, positional, and relational terms such as “up”, “down”, “lateral”, “beneath”, “below”, “lower”, “above”, “upper”, “proximal”, “distal”, and the like may be used herein to describe directions or to describe one element's or feature's spatial relationship to another element or feature as illustrated in the figures. These spatial terms are used relative to reference frames in the figures and are not limited to a particular reference frame in the real world. Furthermore, if a different reference frame is considered than the one illustrated in the figures, then the spatial terms used herein may need to be interpreted differently in that different reference frame. Moreover, the poses of items illustrated in the figure are chosen for convenience of illustration and description, but in an implementation in practice the items may be posed differently.

In addition, the singular forms “a”, “an”, and “the” are intended to include the plural forms as well, unless the context indicates otherwise. Moreover, the terms “comprises”, “comprising”, “includes”, and the like specify the presence of stated features, steps, operations, elements, and/or components but do not preclude the presence or addition of one or more other features, steps, operations, elements, components, and/or groups. Components described as coupled may be electronically or mechanically directly coupled, or they may be indirectly coupled via one or more intermediate components, unless specifically noted otherwise.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition. Moreover, unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within ±1% of the stated value, property, or relationship unless indicated otherwise.

What is claimed is:

1. An information processing system, comprising:
a system board comprising electronic components;
a chassis comprising:
a base supporting the system board;
a pair of side walls;
a front panel; and
a rear panel;
a manifold module, comprising:
a manifold comprising a manifold body defining an interior chamber, a fluid inlet fluidically coupled to the interior chamber, and a plurality of fluid outlets fluidically coupled to the interior chamber; and
a set of mounting arms coupled to the manifold body, each mounting arm comprising a latch configured to engage with a latch point coupled to one of the side walls to mount the manifold module to the chassis in a position outside the chassis adjacent the rear panel or the front panel;
wherein the manifold is configured to, in a mounted state of the manifold module to the chassis and an immersed state of the information processing system in a pool of liquid coolant in an immersion cooling tank, receive via the fluid inlet a flow of the liquid coolant drawn from the pool and expel the flow back into the pool as a plurality of output streams via the fluid outlets, with the output streams being directed towards the rear panel or the front panel.

2. The system of claim 1, further comprising a pair of rails coupled to the side walls, respectively, each of the rails carrying one of the latch points.

3. The system of claim 2, wherein the latch points comprise cable management arm (CMA) latch points configured to removably engage with CMA latches of a CMA to mount the CMA to the rails, and the latches of the mounting arms mimic the CMA latches and are configured to mount the manifold module to the CMA latch points in place of the CMA.

4. The system of claim 1,
wherein each of the fluid outlets comprises an outlet opening through the manifold body, and
wherein at least a subset of the fluid outlets further comprise nozzles fluidically coupled to their respective outlet openings.

5. The system of claim 4, wherein the nozzles are removably coupled to the manifold body.

6. The system of claim 4, wherein at least a second subset of the fluid outlets further comprise plugs covering their respective outlet openings, the plugs being removably coupled to the manifold body.

7. The system of claim 4, wherein at least one of the nozzles has a different flow characteristic than at least one other of the nozzles.

8. The system of claim 1, wherein each mounting arm of the set of mounting arms further comprises:
a beam coupled to and extending from the manifold body;
one of the latches coupled to the beam, the latch comprising:
a latch plate;
an opening through the latch plate; and
a deflectable latch arm coupled to the latch plate and extending into the opening such that the deflectable latch arm is accessible through the opening, the deflectable latch arm configured to engage with an engagement feature of the latch point of the rail to attach the latch arm to the latch point.

9. The system of claim 1, wherein each mounting arm of the set of mounting arms is hingedly coupled to the manifold such that each mounting arm is deflectable with respect to the manifold.

10. The system of claim 1, wherein the manifold module further comprises a set of pump mounting brackets coupled to the manifold body and configured to removably receive a pump.

11. The system of claim 10, wherein a pump mounting bracket of the set of pump mounting brackets further comprises:
a fixed semi-circular lower portion; and
a deflectable semi-circular upper portion movable between an open position and a closed position,
wherein in the closed position, an edge of the upper portion contacts an edge of the lower portion; and
wherein in the open position, the edge of the upper portion is separated from the edge of the lower portion.

12. The system of claim 1, wherein the manifold is positioned adjacent the rear panel and the fluid outlets are configured to direct the output streams towards the rear panel.

13. A manifold module, comprising:
a manifold comprising:
a manifold body defining a hollow interior chamber;
a fluid inlet comprising an inlet opening in the manifold body fluidically coupled to the hollow interior chamber; and
a plurality of fluid outlets comprising outlet openings in the manifold body and fluidically coupled to the hollow interior chamber;
a set of mounting arms coupled to opposite end portions of the manifold body, each mounting arm comprising:
a beam; and
a latch coupled to the beam and configured to removably engage with a cable management arm (CMA) latch point attached to a chassis of an information processing system to mount the manifold module to the chassis; and
a pump mounting bracket coupled to the manifold body and configured to removably receive and hold a pump with the pump coupled to the fluid inlet of the manifold body,
wherein the manifold is configured to, in a mounted state of the manifold module to the chassis and an immersed state of the information processing system in a pool of liquid coolant in an immersion cooling tank, receive via the fluid inlet a flow of the liquid coolant drawn by the pump from the pool and expel the flow back into the pool as a plurality of output streams via the fluid outlets, with the output streams being directed towards the chassis.

14. The manifold module of claim 13, wherein the beams of the mounting arms are coupled to the manifold body by pins, respectively, received in a corresponding openings in the manifold body such that the beams are pivotable with respect to the manifold body.

15. The manifold module of claim 13, wherein the latch is configured to engage with a corresponding receptacle on a rail coupled to a chassis.

16. The manifold module of claim 15, wherein the latch comprises a latch plate and a latch arm coupled to the latch plate, the latch arm being deflectable relative to the latch plate such that the latch arm engages with the corresponding receptacle.

17. The manifold module of claim 13, wherein the pump bracket comprises:
a lower bracket portion; and
an upper bracket portion disposed adjacent and opposite to the lower bracket portion,
wherein at least one of the lower bracket portion and the upper bracket portion is movable with respect to the manifold body.

18. The manifold module of claim 13, further comprising the pump mounted to the pump mounting bracket and fluidically coupled via a liquid conduit to the fluid inlet of the manifold body, the pump is configured to move liquid coolant through the fluid inlet and direct the liquid coolant out at the plurality of fluid outlets.

19. A method for adapting an information processing system for immersion cooling, comprising:
positioning a manifold module outside a chassis of the information processing device adjacent a front panel or a rear panel of the chassis, the manifold module comprising a manifold and mounting arms coupled to the manifold;
coupling the manifold module to the chassis by engaging the mounting arms with cable management arm (CMA) attachment points coupled to the chassis such that fluid outlets of the manifold are arranged to, on condition of a flow of liquid coolant being supplied to a fluid inlet of the manifold, expel output streams of the liquid coolant directed towards the chassis.

20. The method of claim 19, further comprising:
coupling a pump to the manifold by one or more brackets coupled to the manifold;
coupling the pump to a power supply connector on the system board; and
fluidically coupling the pump to a fluid inlet of the manifold.
